(19) United States
(12) Patent Application Publication
(10) Pub. No.: US 2008/0192781 A1
(43) Pub. Date: Aug. 14, 2008

(54) Semiconductor Light Emitting Device

(75) Inventors: James C. O'Gorman, Dublin (IE); Brian J. Kelly, Dublin (IL); John A. Patchell, Dublin (IL)

Correspondence Address: BROOKS, CAMERON & HUEBSCH , PLLC, 1221 NICOLLET AVENUE , SUITE 500, MINNEAPOLIS, MN, 55403, US

(73) Assignee: EBLANA PHOTONICS LIMITED, Dublin (IE)

(21) Appl. No.: 11/661,954

(22) PCT Filed: Sep. 5, 2005
(86) PCT No.: PCT/EP2005/054374

§ 371 Date: Mar. 10, 2008

(30) Foreign Application Priority Data
Sep. 3, 2004 (EP) 04104274.8

(51) Int. Cl. H01S 5/065; H01L 21/02; H01S 5/10; H01S 5/22

(52) U.S. Cl. 372/20; 438/39; 372/44.01; 257/E21.002

(57) ABSTRACT

The present invention relates in general to semiconductor light emitting devices and in particular to methods of altering the spatial emission patterns of such devices. A known problem with these prior art light emitting devices (and laser diodes in general) is that their far-field emission patterns are elliptical and astigmatic in nature. The present invention addresses this problem by refractive index perurbations in the semiconductor device aligned in a direction substantially transverse to the light emission direction to achieve a desired spatial distribution of the emission.

### FIELD OF THE INVENTION

The present invention in general relates to semiconductor light emitting devices and in particular to methods of altering the spatial emission patterns of such devices.

### BACKGROUND

A laser diode is a laser where the active medium is a semiconductor p-n junction similar to that found in an edge-emitting light emitting diode or a super luminscent diode. In a laser diode, the semiconductor crystal is fashioned into a laminar rectangle which is very thin in one direction and rectangular in the other two. The top of the crystal is n-doped, and the bottom is p-doped, resulting in a large, flat p-n or p-i-n junction. The two ends of the crystal are cleaved so as to form perfectly smooth, parallel edges; two reflective parallel edges are called a Fabry-Perot cavity. Photons emitted in precisely the right direction will be reflected several times from each end face before they are emitted. Each time it passes through the cavity, the light is amplified by stimulated emission and losses occur through light scattering or absorbtion. Hence, if there is more amplification than loss, the diode begins to “lase”. Fabry-Perot laser diodes incorporating discrete refractive index perturbations have been shown to operate in a single longitudinal mode over a wide temperature range, see for example, EP 1 214 763 in the name of Trinity College Dublin and PCT/IE/04/00091 of Eblana Photonics Limited (a copy of which is included in appendix 1 of this application) the contents of which are incorporated herein explicitly and by reference. So called “slotted lasers”, which achieve single longitudinal mode emission by means of optical feedback resulting from the formation of slot features along the laser cavity, are also disclosed in Irish Patent No S82521 (National University of Ireland, Cork), the contents of which are incorporated by reference. The type of laser diode just described is called a double heterostructure laser diode or quantom well laser diode if the gain medium consists of quantom wells.

For ease of description the term “slot” will be taken to include a slot etched, or otherwise formed, in a part of the laser cavity as well as any other form of discrete refractive index perturbation which has the effect of modifying optical feedback within the cavity. Exemplary refractive index perturbation means are disclosed in the prior art cited above.

A known problem with these prior art light emitting devices (and laser diodes in general) is that their far-field emission patterns are elliptical and astigmatic in nature. This is the angle of the laser emission cone is different in the directions perpendicular and parallel to the p-n junction plane. This leads to the well known effect called astigmatism where the focal points and divergence of the emission is different in the two perpendicular planes, the impact of which is that the laser emission cannot be properly collimated or brought to a focus using simple lenses. It will be appreciated, in contrast to for example a circular non-astigmatic far-field emission pattern, that astigmatic emission presents significant focussing difficulties. Optical focussing solutions (for example aspherical lenses) are available which correct for the elliptical pattern. However, these solutions are generally extremely complex and expensive.

Jing-Kaung Chen and SiChen Lee, “AlGaAs/GaAs Visible Ridge Waveguide Laser with Multicavity Structure”, IEEE Journal of Quantum Electronics. Vol. QE-23, No. 23, No. 8, August 1987 discloses a ridge waveguide laser exhibiting fundamental transverse mode operation with output power more than 13 mW under pulsed operation.

U.S. Pat. No. 4,783,788 discloses semiconductor lasers which operate in the fundamental lateral and transverse mode.

WO02/31863 discloses a ridge waveguide device having a defect defining region in which the width of the ridge is greater in the defect defining region than in adjoining regions of the ridge.

US2002/0085604 discloses a laser diode whose output is largely single mode.

Another solution which has been used in the prior art to ameliorate the ellipticality of laser diode far-field emission patterns is that of burying the layer heterostructures within another lower index semiconductor material. In these devices, a layer of low bandgap material is sandwiched between two high bandgap layers. One commonly-used pair of materials is GaAs with AlGaAs. The process for burying the laser heterostructures is however extremely complex and requires at least one re-growth stage (a single mode laser requires at least two re-growth stages). A further disadvantage is an effective reduction in power output due to a reduction in the laser cross sectional area and hence volume. However, an advantage of a buried heterostructure laser is its greater efficiency of converting electrical energy to light energy since the region where free electrons and holes exist simultaneously—the “active” region-is now also more confined to the thin middle layer. This means that many more of the electron-hole pairs can contribute to amplification-not so many are left out in the poorly amplifying periphery. In addition, light is reflected from the heterojunction; hence, the light is confined to the region where the amplification takes place.

Accordingly, it is an object of this invention to provide for an improved method of providing a substantially circular far-field emission pattern from a light emitting device. Another object is to provide a method which does not require re-growth. A further object of the invention is to provide a method which can be used easily with other mode engineering techniques to provide simple wavelength circular emissions without re-growth.

### SUMMARY OF THE INVENTION

In the present invention, one or more (refractive) index perturbations substantially aligned to effect the electromagnetic field distribution in one direction in a light emitting device may be used to alter the electromagnetic field distributions along another direction within the device. For example, slots placed in a longitudinal series in a laser to effect the longitudinal electromagnetic field distribution with suitable selection of the slots (index perturbations), the far-field emission pattern may also be altered to a desired configuration (for example a circular pattern). Previously, the main purpose of introducing(refractive) index perturbations was to modify the emission wavelength spectrum of laser diodes. The present application ameliorates the ellipticality of laser diode far-field emission patterns without burying the layer heterostructures within another lower index semiconductor material.

The present invention provides for the introduction of index perturbations into a laser device to modify its far-field emission pattern without altering the spectral characteristics of a laser as well, i.e. the distributions in these other directions may be independently modified without affecting the spectral characteristics of the device in question. This is because it is primarily the positions of the interfaces associated with the slot features along the cavity, which influence the spectral characteristics of a laser diode, while it is a combination of the shape, length and/or depth of the perturbations which determine how the lateral and transverse electromagnetic field distributions within the device will be modified. Thus it is possible to use a pattern of index perturbation principally arranged along one direction to modify electromagnetic field distributions in one or both of the other two orthogonal directions, while having either a negligible or even a profound effect on the spectral characteristics of the device. Although, it will be appreciated that modifying the spectral characteristics may alter the far-field emission pattern.

One embodiment of the invention provides a method of modifying the electromagnetic field distributions in one or more directions in a laser/light emitter by using a pattern of index perturbations principally arranged in one direction.

Another embodiment provides a way of modifying the field distribution in one direction in a laser light emitter using a pattern of index perturbations principally arranged along another direction. A further embodiment provides a method of modifying the far-field emission pattern independently of the spectral characteristics using a set of index perturbations arranged principally in one direction.

Another embodiment provides a method of manufacturing a semiconductor device for emitting light in a first direction comprising the step of creating at least one index perturbation in the semiconductor device aligned in a direction substantially transverse to the first direction to achieve a desired spatial distribution of the emission. The at least one index perturbation may comprise a pattern of index perturbations. Suitably, the semiconductor device comprises a laser, for example a ridge waveguide laser. More particularly, the semiconductor device may be a slotted laser, in which case the index perturbation may be provides as a slot. One or more of the following: slot depth, slot length and slot shape may be suitably selected to contribute to the desired emission pattern.

The index perturbation may be provided by one or the following or a combination thereof: introduction of a dopant, etching and ion implantation.

A further embodiment of the invention provides a method of modifying the field distribution in one direction in a laser light emitter using a pattern of index perturbations principally arranged along another direction.

A further embodiment of the invention provides a method of modifying the far-field emission pattern of a semiconductor light emitting device independently of the spectral characteristics using a set of index perturbations arranged principally in one direction.

Still a further embodiment provides a semiconductor light emitting device comprising a longitudinal active region for producing the light and one or more effective refractive index perturbations disposed along the longitudinal axis and aligned transverse thereto, wherein at least one of the refractive index perturbations is dimensioned to effect a desired emission pattern from the active region. The device may be a laser, for example a ridge waveguide laser. If the laser comprises a ridge, the at least one perturbation may be formed by a slot defined in the ridge. In which case, the length, depth and or shape of the slot may be selected to contribute to a desired far-field emission pattern. Similarly, the at least one effective refractive index perturbation may be formed by one or more indentations defined in the side of the ridge of the laser or more generally by indentations defined in the ridge. The semiconductor light emitting device may also be an LED, for example an edge-emitting LED.

A still further embodiment of the invention provides a method of manufacturing a laser comprising the steps of: (1) forming a laser cavity with a lasing medium, the laser cavity defining a longitudinally extending optical path and having a facet at either end, and (2) forming a plurality of perturbations into the laser cavity, wherein the shape and/or dimensions of the plurality of perturbations are selected to provide a desired far-field emission pattern for the laser. The cavity may be formed with a longitudinally extending ridge with at least one perturbation provided by etching a slot in the ridge and wherein at least one of the following:

a) slot depth,

b) slot width, and

c) slot shape,

may be selected to contribute to the desired emission pattern. Similarly, the perturbations may be provided by etching one or more indentations in the side of the ridge.

Yet another embodiment of the invention provides a ridge laser device having a cavity defining a longitudinal axis of the device, the laser being adapted to provide light having a far field emission pattern and wherein, a plurality of index perturbations are provided along the longitudinal cavity, the position of the index perturbations within the cavity effecting a spectral tuning of the laser, the dimension of the index perturbations being selected to effect a modification of the far field emission pattern.

A still further embodiment provides a method of tuning a ridge laser, the method including the steps of providing a first pattern of perturbations to define the spectral emission characteristics of the laser and a second pattern of perturbations to define the spatial emission characteristics of the laser.

A further embodiment provides a ridge wave-guide laser having a substantially non-astigamtic emission pattern. The invention extends to playback devices incorporating such a laser, for example optical disc playback devices. Exemplary optical playback devices would include DVD or CD players. Similarly, the invention extends to recording devices incorporating such a laser, for example optical disc recording devices. Exemplary optical recording devices would include DVD or CD recorders. The invention also extends to display devices comprising such a ridge wave-guide laser.

A further embodiment provides an edge-emitting LED having a substantially non-astigamtic emission pattern. The invention also extends to a light coupler or photo amplifier comprising such an edge-emitting LED

This technique allows for the manufacture of laser diodes with low emission astigmatism, which simplifies the coupling of the emitted light into waveguides and optical fibres. This improved coupling in turns allows for laser diode components which consume less power by being operated less aggressively and consequently for laser driver circuits which consume less power. It also allows for the possibility of lasers with higher powers before the onset of catastrophic optical facet damage.

The technique has application in the manufacture of light emitting devices for sensing and recording systems, e.g. DVD players where a circular and non-astigmatic emission pattern would be preferred. The technique also has application in the field of displays, where it is generally preferred that the pattern caused by individual light devices is non-elliptical and non-astigmatic in nature.

### DESCRIPTION OF DRAWINGS

The invention will now be described in greater detail with reference to the following drawings in which:

FIG. 1 is an example of prior art ridge laser with a slot;

FIG. 2 is a top view of the prior art ridge laser of FIG. 1;

FIG. 3 illustrates an exemplary slot arrangement in a ridge laser;

FIG. 4 is a mirror loss spectrum from a device containing the pattern of index perturbations shown in FIG. 3;

FIG. 5 is an illustration demonstrating the effect of a slot on the spatial orientation of the propagating electromagnetic field;

FIG. 6 is an exemplary perpendicular far field of a laser according to the invention containing index perturbations, with a FWHM 23.9 degrees;

FIG. 7 is an exemplary parallel far field of the same laser as FIG. 6, with a FWHM 23.2 degrees;

FIG. 8 is an exemplary perpendicular far field of a comparable prior art laser not containing index perturbations, with a FWHM 30.2 degrees; and

FIG. 9 is an exemplary parallel far field of the laser of FIG. 8, with a FWHM 22.9 degrees.

### DESCRIPTION OF INVENTION

The invention is based on the principle explained below of how an index perturbation (or pattern thereof) may be used to modify the electromagnetic field distribution within a semiconductor light-emitting device, such as a edge-emitting LED or laser diode. Desirably such an index perturbation is located along one direction of the device such as the longitudinal direction (but aligned in a transverse direction). This is in addition to the conventional uses for such index perturbations, for example in the case of the laser diode, to the spectral characteristics of the device. In fact, as will be explained below, the two aspects may be controlled independently. It should noted that while the concept which forms the basis of this invention is illustrated using a slotted laser having rectangular slot features, that the concept may be applied to other types of light emitting devices, e.g. LEDs, where the electromagnetic field distribution may also be altered by introducing perturbations. Moreover, effects similar to those which will be described here are attainable using index perturbations of other shapes. For examples of such index perturbations see International Patent Application No. PCT/IE04/00091, the entire contents of which are incorporated herein by reference.

In fact, there may be several advantages to using the described perturbations of PCT patent Application No. PCT/IE04/00091 and in particular that the slot lengths may readily be alterable to attain a particular spatial emission pattern without significantly altering the spectral characteristics, thus providing for relatively simple independent control of the spatial emission pattern and spectral characteristics.

However, for ease of explanation, the invention will now be described with reference to a conventional slotted laser with rectangular slots. While the description of the present invention which follows refers primarily to the case where the perturbations are defined by slots etched along the device it will be appreciated by a person skilled in the art that the teaching of the invention is equally applicable to other forms of perturbations (for example modifying the refractive index profile by employing doping or ion implantation methods).

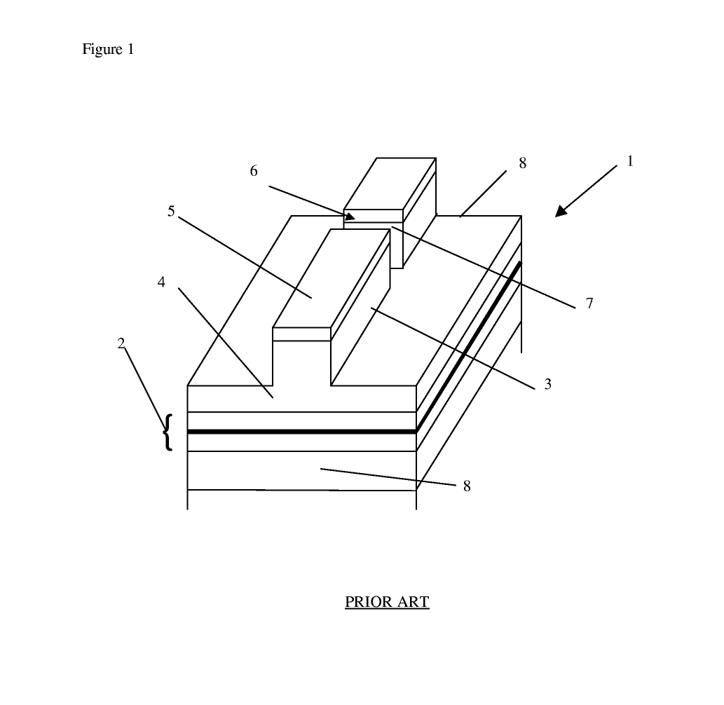

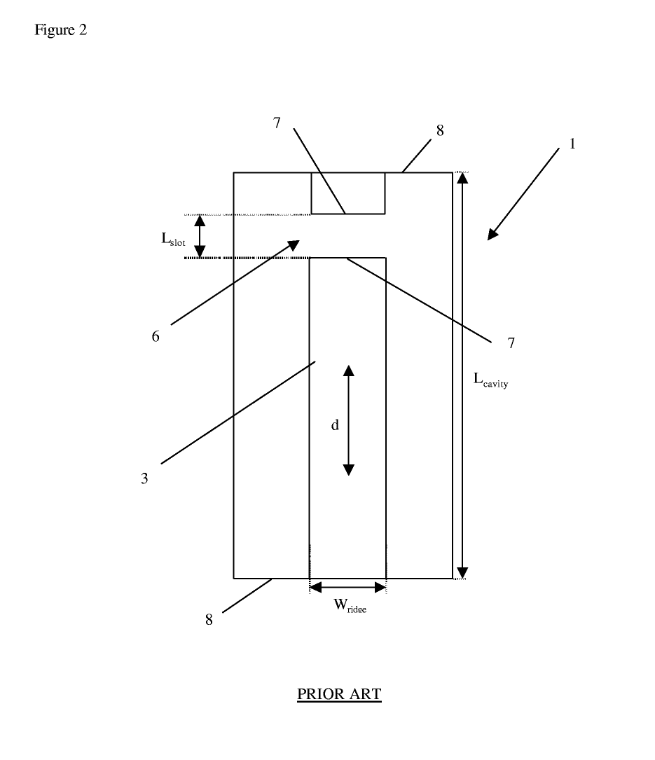

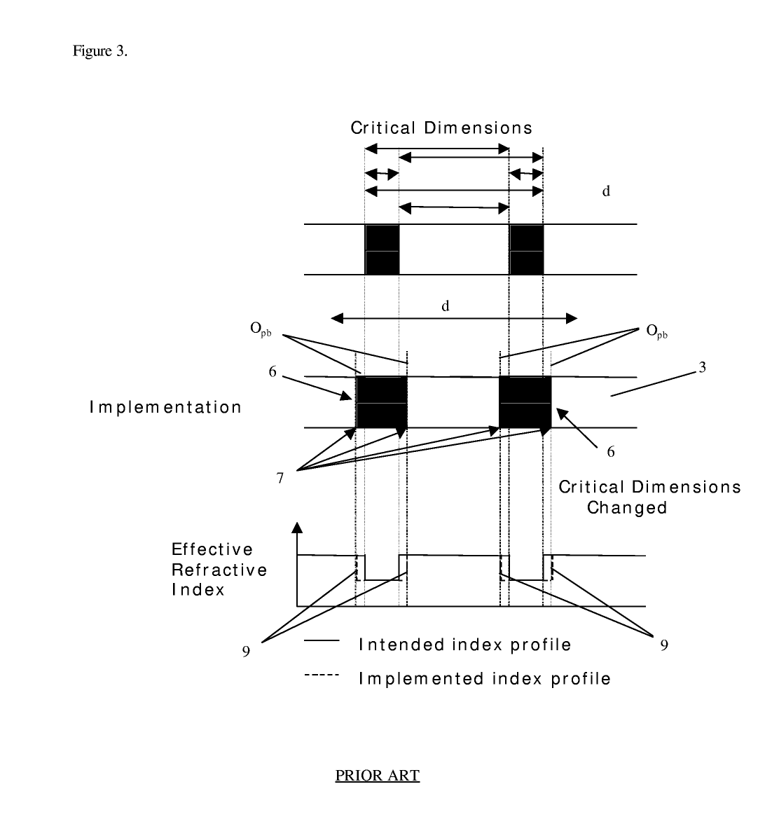

FIGS. 1 and 2 illustrate a typical prior art slotted laser 1 having a single rectangular slot 6 in which the present invention may be employed. Typically, such a device comprises waveguiding layers 2 (containing for example a multiple quantum well structure) covered by an upper cladding layer 4. Primary optical feedback means are provided in the form of a cleaved facet 8 at either end of the device. The distance between the facets determines the exact wavelengths of the Fabry-Perot modes of the cavity. A ridge 3 is formed in the upper cladding layer 4 which also has a cap layer 5, which in turn may or may not be doped and is generally used as an electrical contact. The slot features in such known devices are formed by etching a rectangular slot 6 in the ridge waveguide 3, resulting in two longitudinal interfaces 7 that are perpendicular to the direction of light propagation, d, within the device.

Slotted lasers including those of the present invention may be used to obtain a desired spectral characteristic, e.g. a fundamental frequency from the laser. Moreover, the desired spectral characteristic may be defined by the single mode suppression ratio of the device. For most single frequency applications, a Side Mode Suppression Ratio of 30 dB or more is desired and in some a ratio of 35 dB or more is required. Devices having these figures may be readily fabricated using methods of the present invention.

The mechanism where by slotted lasers achieve their single mode performance may be exemplarily described as follows:

It is well known that the free spectral range of a laser is given by

$$Δλ = \frac{{λ}^{2}}{2 {n}_{eff} L} \qquad ( 1 )$$

and as such is in effect determined by the cavity length, L, of the device, where, Δλ, is the free spectral range, λ, is the free space wavelength of the light and, n_{eff}, is the effective index of the optical mode in the laser cavity.

However, it is observed that by placing reflective interfaces in the laser cavity at intervals separated L/N it is possible to enhance approximately every Nₜₕ Fabry Perot mode, where L is again the cavity length of the laser and N is an integer. This is essentially what occurs in a slotted laser, except for the fact that when a rectangular slot feature is etched into a laser cavity, two reflective interfaces are created simultaneously.

In order for rectangular slots to be efficient at modifying the mirror spectrum of a laser diode, the length of the slot must generally obey the following relation.

$${l}_{slot} = \frac{n λ}{4 {n}_{eff}} where n = 1 , 3 , 5 … \qquad ( 1 )$$

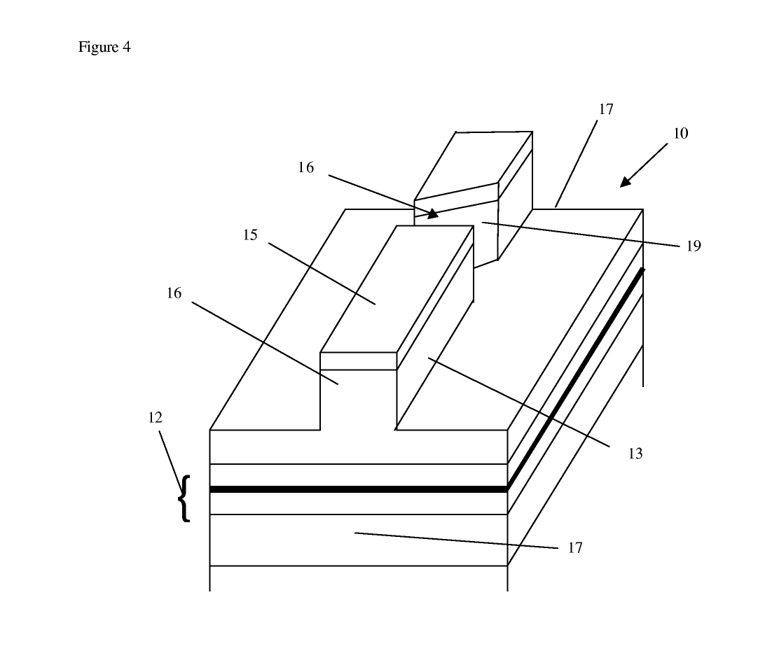

Adherence to this criterion ensures constructive interfere between reflections from both sides of the index perturbations. It will be appreciated that in the context of the present invention, the term ‘slot length’ refers to the distance between the longitudinal slot faces in the device material, i.e. slot length is measured along the direction of light propagation. Now consider the configuration (pattern) of slots shown in FIG. 3. If positioned appropriately in the laser cavity this slot configuration will result in a mirror loss spectrum similar to that shown in FIG. 4. Also since the length of the slots in this pattern only have to obey Equation 1, there are a number of slot lengths which will result in the same mirror loss pattern. It is noted that the arrangement of slots shown in FIG. 3 is non-regular or non-periodic, however this concept works equally well with either periodic or non-periodic patterns of index perturbations. It is also to be noted that other patterns exist which are not amenable to simple explanation as above and for simplicity of explanation will not be described herein, nonetheless it will be appreciated by those skilled in the art that the present invention may be readily applied to these.

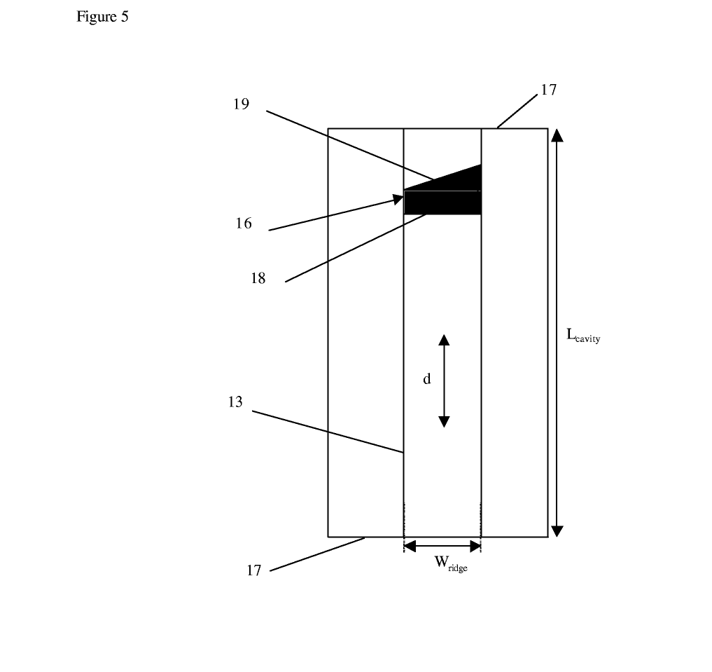

However, in accordance with the teachings of the present invention it will be understood that slot patterns with different slot lengths will have different effects on the transverse electromagnetic field distribution within the laser diode, and thus can used to tailor the transverse far-field emission profile. The basis of this effect is as follows. As the far-field emission profile is the Fourier transform of the near-field intensity profile, the larger the extent of the near-field profile the narrower the far-field emission profile will be. Now consider FIG. 5, this illustration shows that the transverse field distribution underneath the slot is wider than under other parts of the ridge. As the field at the facet may be considered as a hybrid of both the field under the ridge and the field under the slot, the effect of introducing the index perturbations of the type shown in FIG. 3 is to broaden the near-field and narrow the far-field. Thus it is possible to independently modify the far-field with out affecting the spectral characteristics of the device. Accordingly, it is possible to select a particular arrangement, dimensioning and/or shaping of slots to independently achieve desired spectral and spatial emission characteristics. As such, the typically astigmatic emission pattern of such lasers may be modified to a more desirable pattern such as an generally circular or non astigmatic pattern without requiring the complex optical corrections or re-growths that were required for prior art devices.

Experimental Data

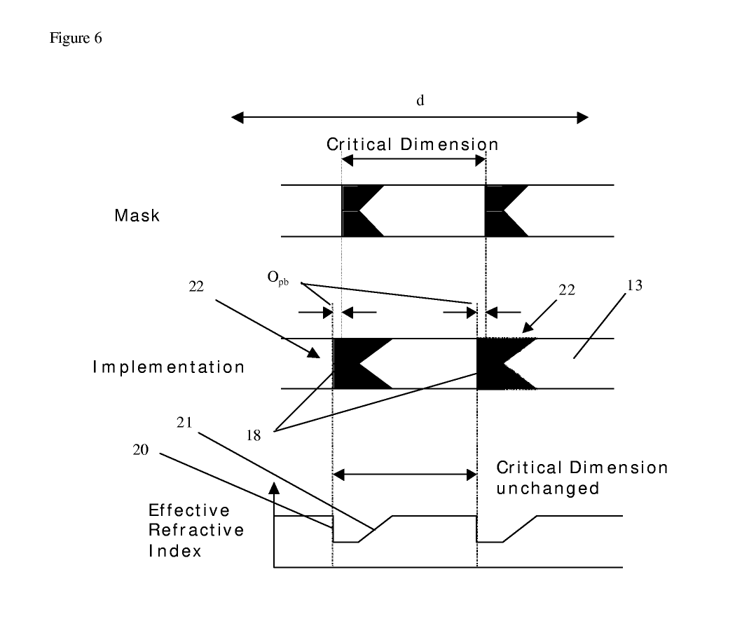

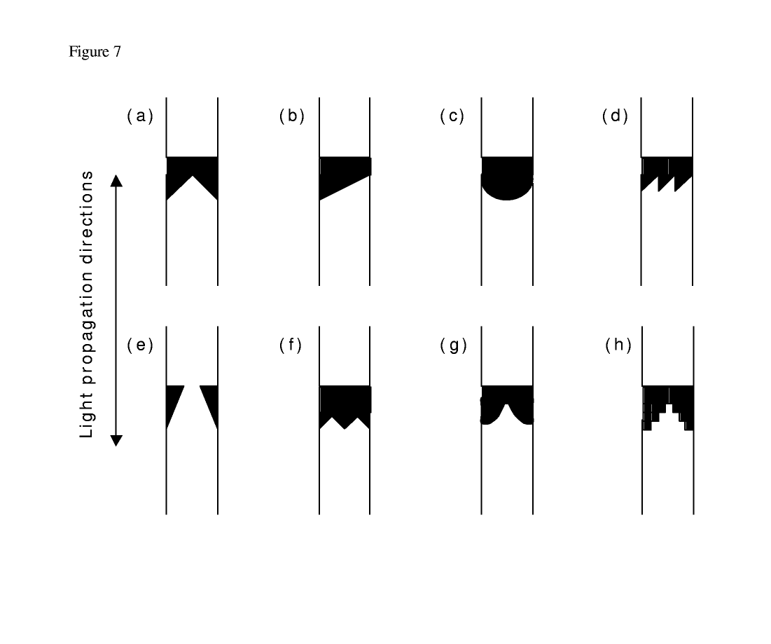

The slot patterns which produced the perpendicular and parallel farfield profiles shown in FIGS. 6 and 7 can consist of between 16 and 22 slots. Each slot feature is etched to a depth where the effective index of the transverse mode beneath the slot is approximately 4.0×10³ less than the effective index of the unperturbed mode. The length of the slot features used to create this effect can be in the range 0.8 μm to 1.5 μm. It is of course recognised by people skilled in the art that there are other slot configurations that will also give rise to improved farfield patterns.

FIG. 6 shows the transverse (perpendicular) far-field profile for a laser containing a number of index perturbations, ie in accordance with the present invention, from which it will be seen that the Full Width Half Maximum (FWHM) divergence of the light emitted in this case is 23.9 degrees, whereas FIG. 7 shows the parallel far-field profiles for the same laser where the FWHM divergence is 23.2 degrees. Accordingly, the ratio between the two FWHM values for this example, is 1.03 which is effectively non-astigmatic. It will be appreciated that in the context of the present application and in contrast to the prior art that differences of less than 5 degrees between FWHM perpendicular and parallel far fields may be readily achieved without compromising other characteristics of the device. Moreover, differences of 2 degrees are obtainable without difficulty. Furthermore, as shown by the example a difference of less than one degree is possible. In all of these cases, the FWHM may be less than 27 degrees and preferably less than 25 degrees.

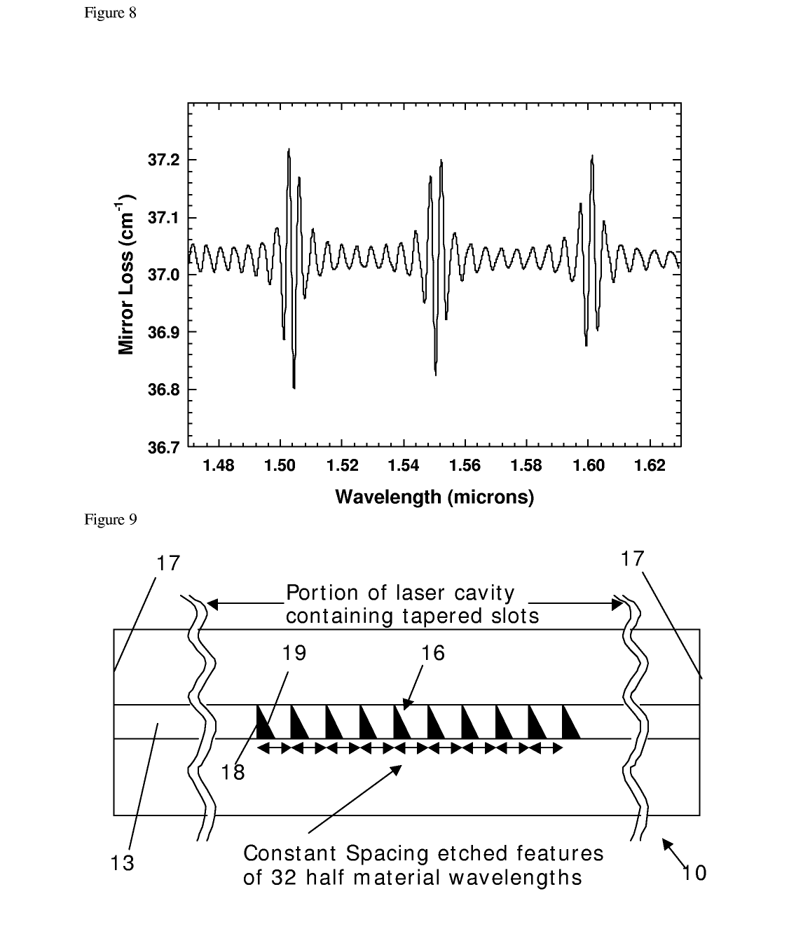

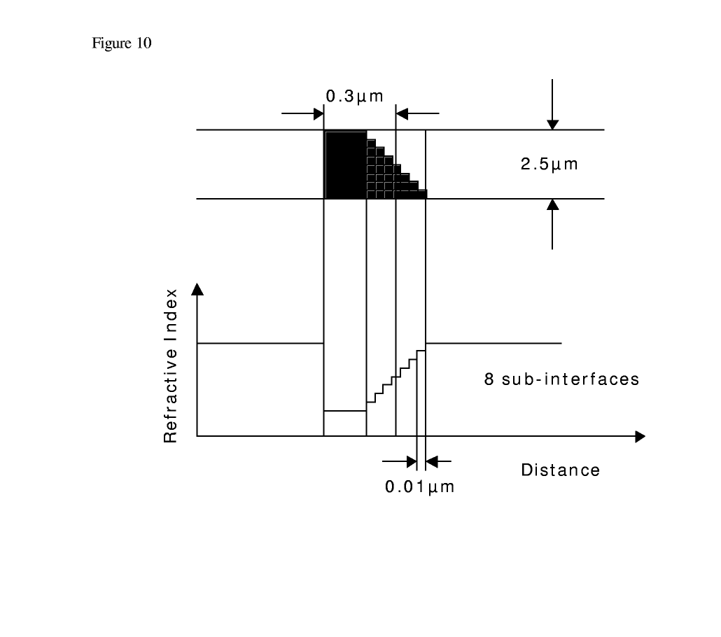

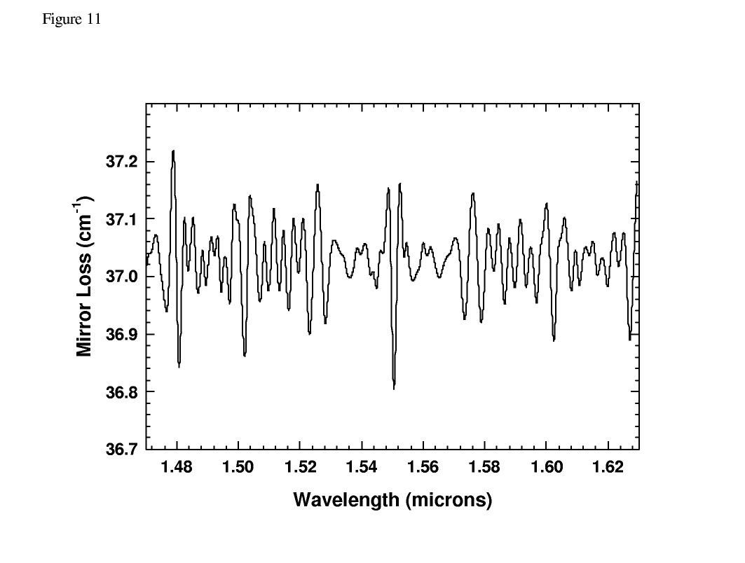

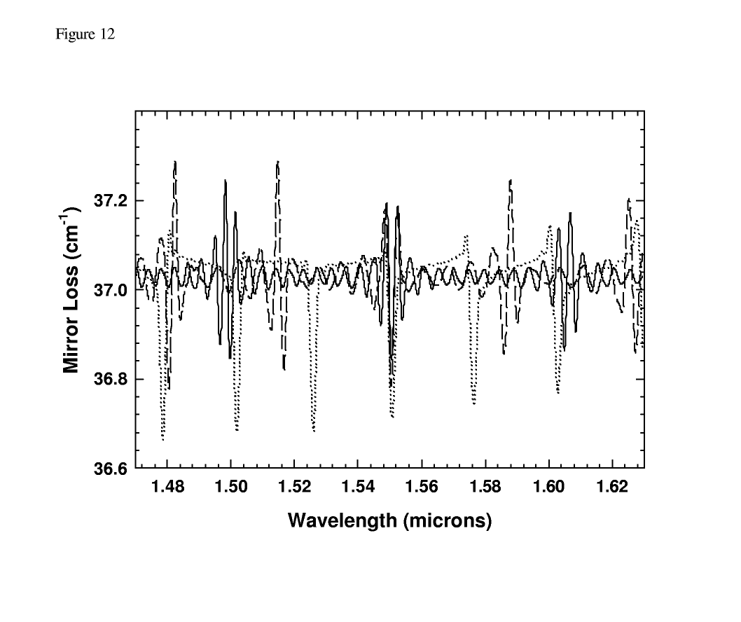

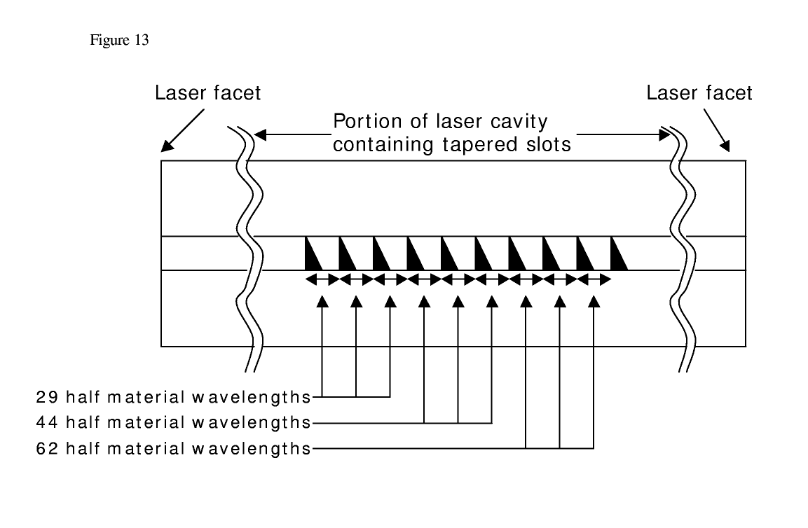

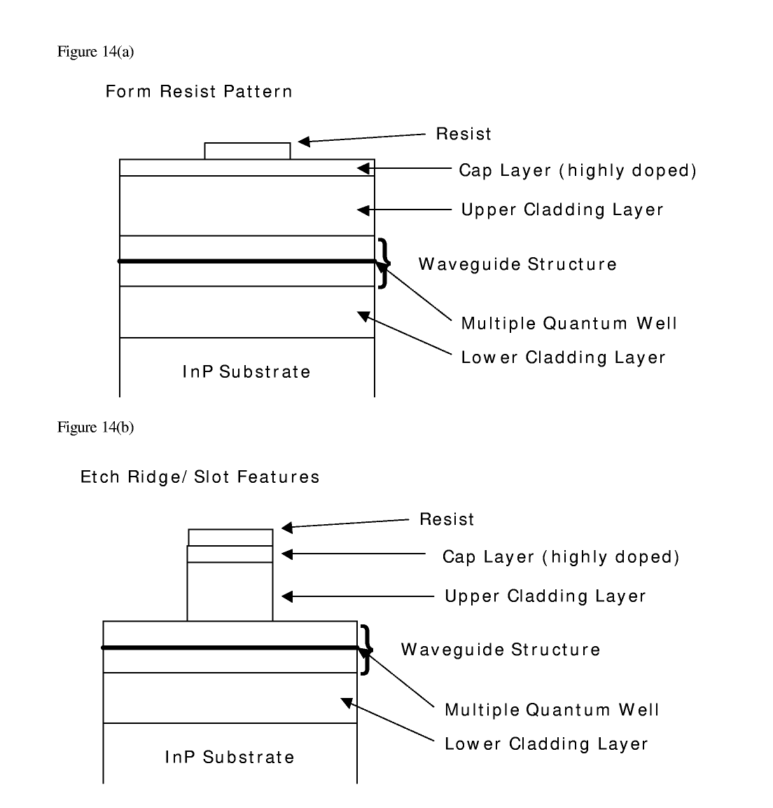

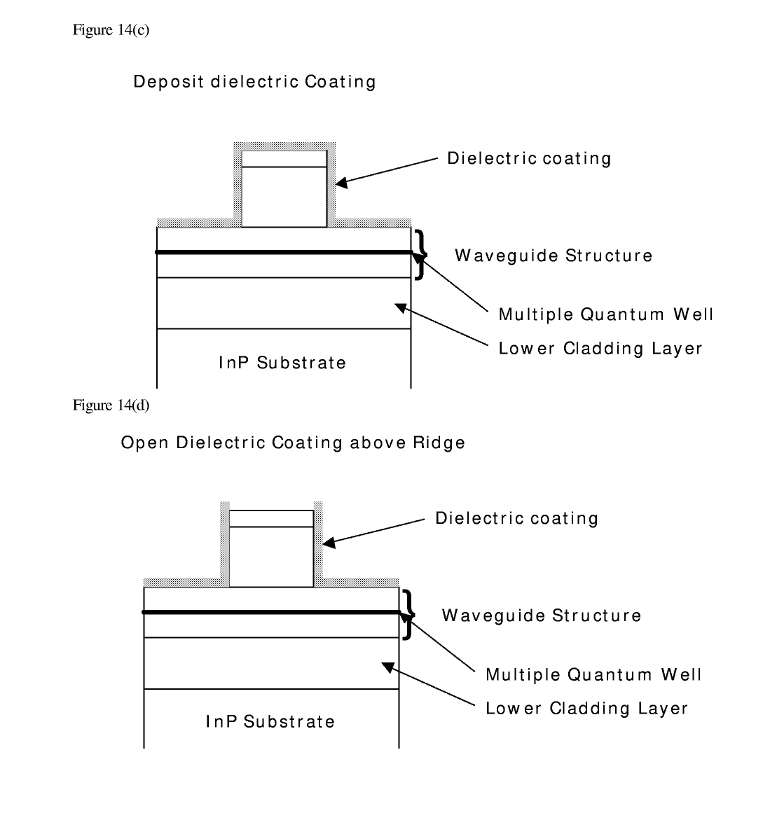

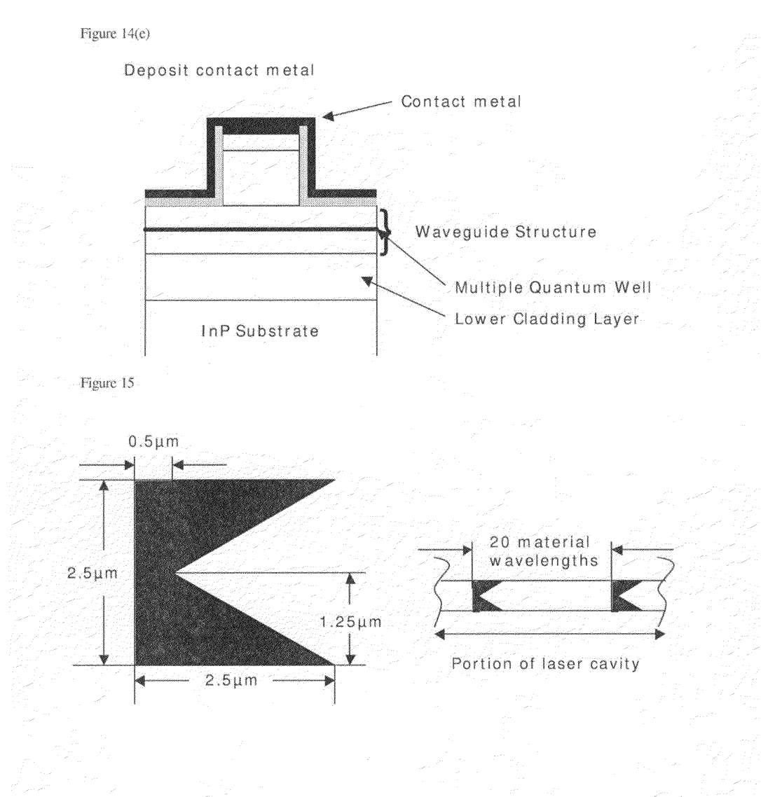

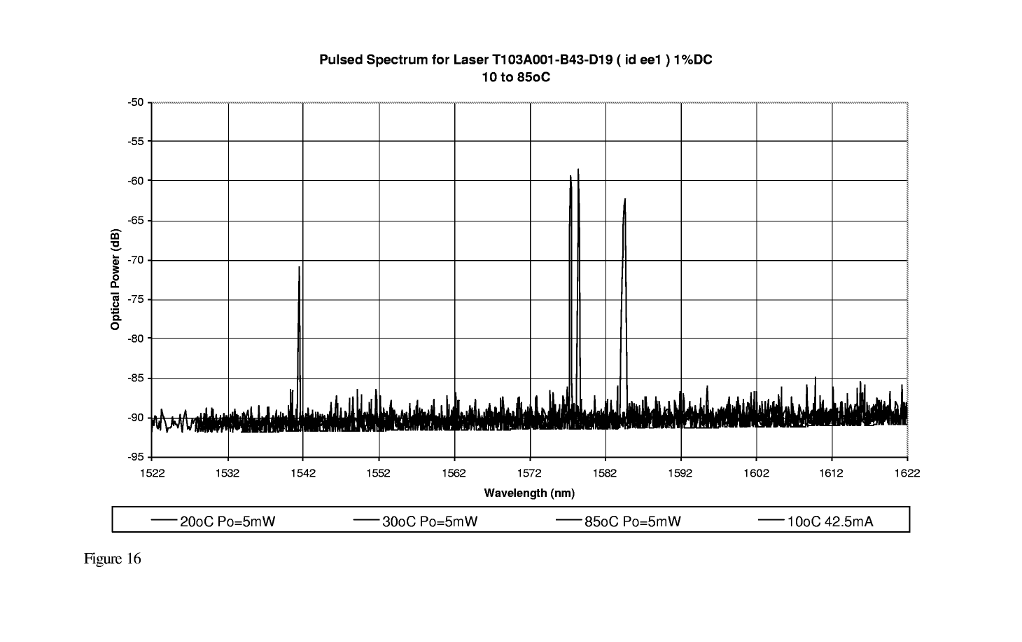

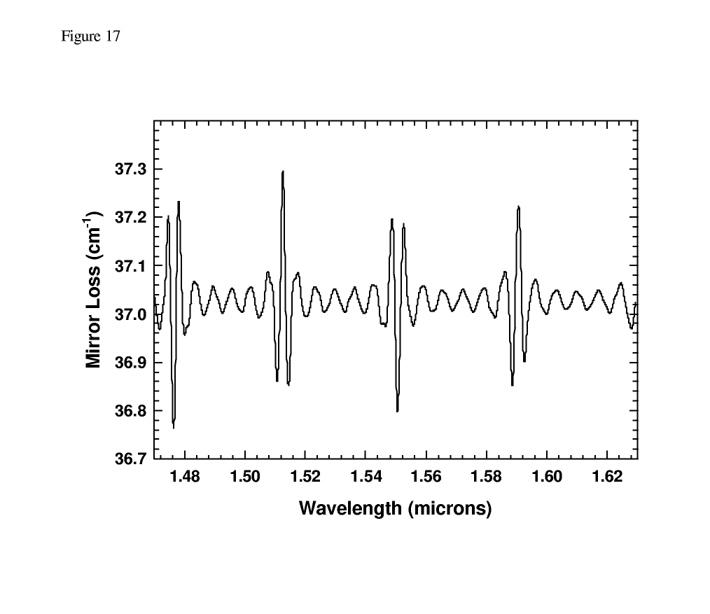

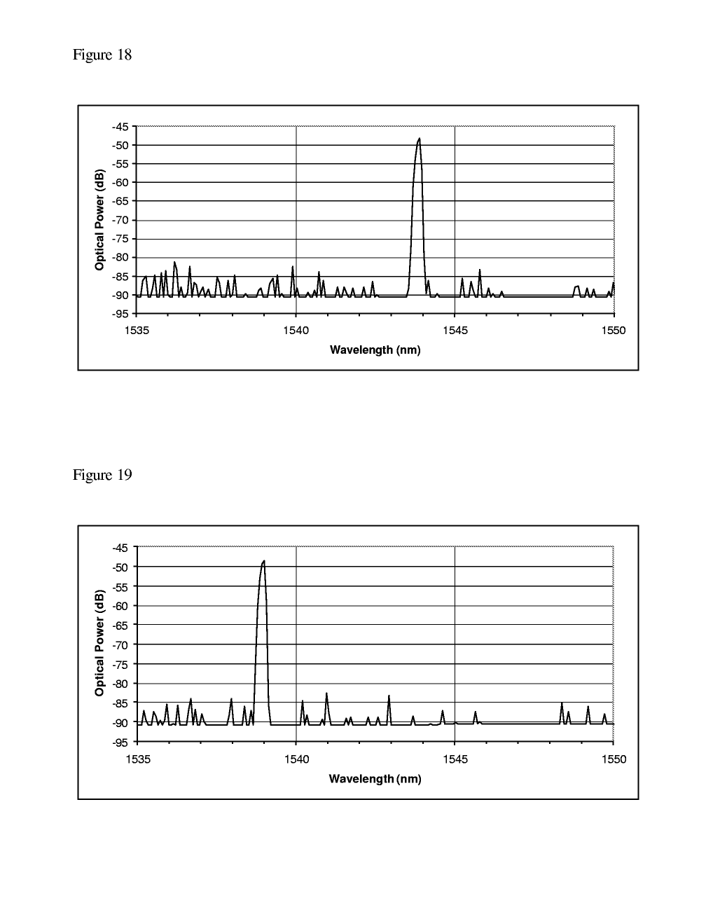

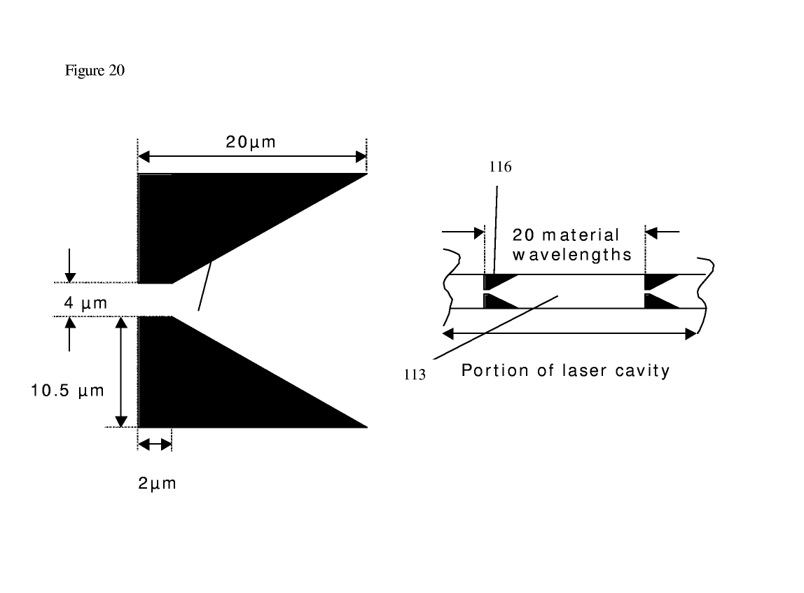

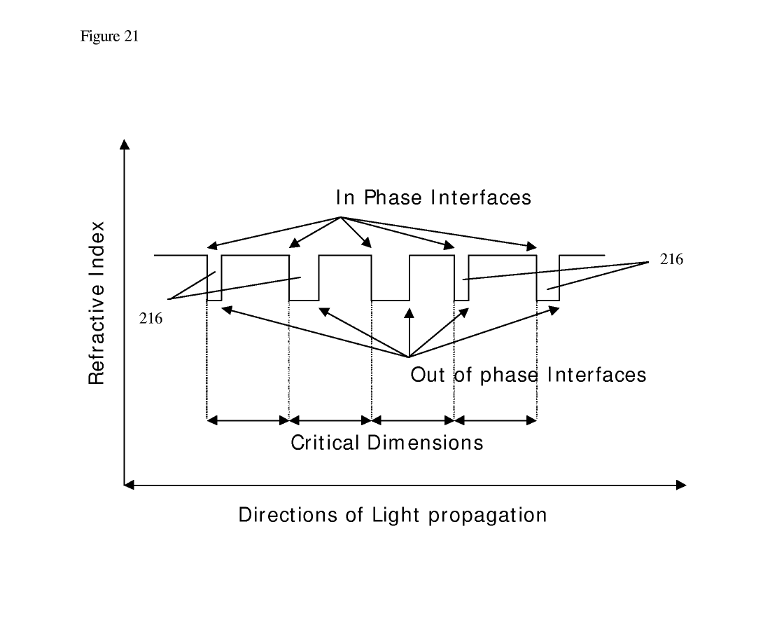

The FIGS. 8 and 9 show the perpendicular and parallel farfield profiles which result form an unperturbed ridge waveguide. It is noted that the presence of etched slot features may adversely affect the farfield emission pattern of a laser diode. As an example consider a pattern of 10 or more slots, all of which are etched to a depth where the effective index of the transverse mode under any feature is at least 0.8×10⁻² less than the effective index of the unperturbed mode. If the length of the slot features is kept under 0.5 μm in length the transverse farfield is unaffected. However if the slot length is increased beyond 0.5 μm shape of the transverse profile is significantly altered making it suitable for coupling into single mode fibres.

In contrast FIG. 8 shows the equivalent transverse (perpendicular) far-field profile for a traditional laser not containing any index perturbations and designed for reduced astigmatism by careful selection of ridge width, height and change in effective index of refraction. In this instance, the Full Width Half Maximum divergence of the light emitted in this case is 30.1 degrees and the parallel field is shown in FIG. 9, where the FWHM is 22.9 degrees and the ratio between them is 1.32 (considerably astigmatic) In the particular case of FIGS. 7 and 8, the lateral far-field pattern has not been altered by the slot pattern.

However, a pattern of index perturbation arranged principally along one direction could be designed to accomplish this task. In the exemplary case shown, it was not necessary as modifying the transverse (perpendicular) far field was enough to remove the astigmatism from the laser emission pattern.

The present invention provides a method for making reliable, easily manufacturable and hence relatively inexpensive light emitting devices having a desired far-field emission pattern. Such devices have instant application in the field of fibre-optic telecommunications both in transmission lasers and also semiconductor optical-amplifiers since it may be used to improve coupling efficiency between the semiconductor waveguide and the input and output optical fibres. The devices also have application in laser display systems. It will be appreciated that the availability of devices with a desired far-field emission pattern (e.g. circular) has knock-on effects to other parts of systems and includes benefits such as improved coupling efficiency, reduced power, less complex optics.

Devices described herein also have instant application in laser playback and recording devices, where to date complicated methods have been employed to overcome the elliptical nature of the laser beams.

It should be noted that many other applications of the method and devices are considered possible and the relevant applications are not limited to those specifically recited above. Also, the present invention may be embodied in other specific forms. The embodiments described above are to be considered in all respects as illustrative and not restrictive in any manner.

### APPENDIX 1

A copy of PCT/IE/04/00091 is included below and incorporated specifically herein as the devices and/or slot patterns described may be advantageously employed in the context of the present invention. Similarly, the methods of manufacture described may also be employed. Thus the scope of the present invention extends to include the use of these devices/slot patterns and methods in conjunction with this invention. It will be appreciated that the reference numerals and drawings referred to below are contained in the drawings for Appendix 1, which are appended to the drawings of the present invention but marked as the drawings for appendix 1.

### Semiconductor Laser and Method of Manufacture

### FIELD OF THE INVENTION

The present invention relates a semiconductor laser, in particular such a laser which operates with substantially single longitudinal mode emission.

### Background

Achieving single mode emission by introducing perturbations at prescribed positions along the length of a device is known, see EP 1 214 763 (Trinity College Dublin) the contents of which are incorporated herein by reference. So called “slotted lasers”, which achieve single longitudinal mode emission by means of optical feedback resulting from the etching of slot features along the laser cavity, are also disclosed in Irish Patent No S82521 (National University of Ireland, Cork).

In general terms, the perturbations may be caused by any index altering means which modifies the refractive index profile of the waveguide to an appropriate degree to manipulate optical feedback and hence the spectral content of the device. While the description of the present invention which follows refers primarily to the case where the perturbations are defined by slots etched along the device it will be appreciated by a person skilled in the art that the teaching of the invention is equally applicable to other forms of perturbations (for example modifying the refractive index profile by employing doping or ion implantation methods).

The term ‘slot length’ (designated Lₛₗₒₜ in FIG. 1) as used herein refers to the distance between the longitudinal slot faces in the device material, i.e. ‘slot length’ is measured along the direction of light propagation, d. FIGS. 1 and 2 illustrate a typical prior art slotted laser 1 having a single rectangular slot 6. Typically such a device comprises waveguiding layers 2 (containing for example a multiple quantum well structure) covered by an upper cladding layer 4. Primary optical feedback means are provided in the form of a cleaved facet 8 at either end of the device. The distance between the facets determines the exact wavelengths of the Fabry Perot modes of the cavity. The upper cladding layer 4 forms a ridge 3 having a cap layer 5. The slot features in such known devices are formed by etching a rectangular slot 6 in the ridge waveguide 3, resulting in two longitudinal interfaces 7 that are perpendicular to the direction of light propagation, d, within the device.

The mechanism where by slotted lasers achieve their single mode performance may be described as follows:

It is well known that the free spectral range of a laser is given by

$$Δλ = \frac{{λ}^{2}}{2 {n}_{eff} L} \qquad ( 1 )$$

and as such is in effect determined by the cavity length, L, of the device. Where, Δλ, is the free spectral range, λ, is the free space wavelength of the light and, n_{eff}, is the effective index of the optical mode in the laser cavity. However it is observed that by placing reflective interfaces in the laser cavity at intervals separated L/N it is possible to enhance approximately every Nₜₕ Fabry Perot mode. Where L is again the cavity length of the laser and N is an integer. This is essentially what occurs in a slotted laser, except for the fact that when a rectangular slot feature is etched into a laser cavity, two reflective interfaces are created simultaneously. What is important to note here is that each of the reflective interfaces created provides a similar amount of optical feedback. It is also important to realise that the length of the etched slot features must be kept reasonably small (typically <3 μm). The principal reasons for this are the following: Firstly, the internal loss in the waveguide beneath slots is substantially higher that elsewhere in the cavity. Secondly, since the dopant concentration in the semiconductor material below the bottom of a slot may be less than one tenth of that in the cap layer it is impossible to create a low resistance metal contact on this material. This means that if the length of a slot feature is increased arbitrarily, then a portion of material beneath the slot will remain unpumped.

In order to accurately specify the emission wavelength of a device it is necessary to be able to position all the edges of the slot features relative to each other with an accuracy that is inversely proportional to the distance between them. This can be understood by recognising that the standing wave conditions in a long cavity device are less effected by a fixed change in the length of the cavity, Δx, than the standing wave conditions in a short cavity device. (It is noted that since the facets of a device provide a significant amount of optical feedback, the positioning of these interfaces with respect to the slot features is important). As typical slotted lasers incorporate etched features, the lengths of which are less than an order of magnitude greater than the wavelength of the optical field in the laser cavity. Also given that the two interfaces of a given conventional slot feature provide a significant amount of optical feedback, then it can be appreciated that the emission wavelengths, or more precisely the mirror loss spectra of such devices, are extremely sensitive to errors in the distance between the interfaces of such a feature. The emission wavelength of a slotted laser is thus critically dependent on length of the slot features themselves. The process of accurately realising a slot feature of a given length is therefore also important.

The most important factor in determining the accuracy with which a slot feature can be implemented is the choice of lithographic technique used. This varies between ±10-20 nm for e-beam systems to ±100-200 nm optical lithography systems. Beyond the accuracy of the lithographic system itself, the procedure of realising a rectangular slot feature of a certain length is also severely hampered by the bias associated with etching process (the offset due to process bias is designated Opb in FIG. 3). This is a problem because the length of a slot feature with parallel edges is affected by the bias of the etching process and therefore the critical dimensions in the slot pattern may be changed. As a result of these factors it is difficult, using standard lithographic and processing techniques, to sufficiently control the length of a rectangular slot feature and thus specify the spectral content of a device containing such features.

As discussed above there are considerable difficulties in accurately specifying the emission wavelength of slotted lasers. It is an object of the present invention to address these difficulties.

It is a further object of the invention to provide manufacturing method, which addresses the problems, associated with processing bias and the resulting effect on slot positioning.

It is a still further object to provide a substantially single mode laser whose performance is less temperature dependent.

It is another object of the invention to provide a method of enhancing the free spectral range of a laser and to provide a laser having improved free spectral range.

### BRIEF DESCRIPTION OF THE INVENTION

The present invention provides a laser emitting light of substantially a single wavelength, comprising a lasing cavity with a lasing medium and primary optical feedback means in the form of a facet at either end of the cavity, the laser cavity defining a longitudinally extending optical path; and secondary optical feedback means formed by one or more effective refractive index perturbations in the lasing cavity, each perturbation defining two interfaces; wherein for at least one perturbation, only one of the two interfaces contributes to optical feedback along the optical path.

Preferably the laser comprises a ridge and at least one effective refractive index perturbation is formed by a slot defined in the ridge. In a preferred embodiment each perturbation comprises a slot formed along the ridge.

It is preferred that the contributing interface of each perturbation is substantially planar and substantially perpendicular to the longitudinally extending optical path.

Preferably at least one slot comprises a first face which is substantially planar and substantially perpendicular to the longitudinally extending optical path and a second face which is non-perpendicular to the optical path and is preferably substantially stepped, curved or angled with respect to the first face. Such slot design minimises or prevents destructive interference between interfaces.

According to the invention only the interfaces which are substantially perpendicular to the optical path contribute to optical feedback within the device, with feedback from non-perpendicular interfaces being suppressed thus improving performance characteristics of the laser.

In an alternative embodiment a laser comprising a ridge has at least one effective refractive index perturbation is formed by one or more indentations defined in the side of the ridge. Suitably each perturbation may be formed by indentations defined in the ridge.

Typically a series of effective refractive index perturbations may be employed wherein the spacing between adjacent contributing interfaces is a uniform number of quarter material wavelengths. One or more additional series of effective refractive index perturbations may be overlaid with a first series of perturbations. Such series of perturbations result in devices with a larger effective free spectral range.

In a further embodiment two or more slots are of different length (while the spacing between adjacent contributing faces is a uniform number of quarter wavelengths). The effect of such ‘chirped’ slots is that the contributing faces can result in constructive interference of the optical feedback within the cavity whereas the non-contributing faces do not since the lengths of individual slots are different from each other.

The present invention also relates to a method of manufacturing a laser comprising the steps of: (1) forming a laser cavity with a lasing medium, the laser cavity defining a longitudinally extending optical path and having a facet at either end, and (2) forming optical feedback means by introducing a plurality of perturbations into the laser cavity, each perturbation defining two longitudinal interfaces; characterised in that, the longitudinal interfaces of at least one perturbation are adapted such that only one interface contributes to optical feedback along the longitudinally extending optical path. That is to say that, for at least one perturbation, only one interface contributes to optical feedback along the longitudinally extending optical path.

Preferably the cavity is formed with a longitudinally extending ridge and at least one perturbation is provided by etching a slot in the ridge.

Preferably at least one slot is formed with a first face which is substantially planar and substantially perpendicular to the longitudinally extending optical path and a second face which is non-perpendicular to the optical path and is preferably substantially curved, stepped or angled with respect to the first face. Alternatively perturbations may be provided by etching one or more indentations in the side of the ridge.

The method of the invention improves processing tolerances and enhances temperature characteristics of the resultant laser as shall be described further below.

The invention also provides a method of enhancing the free spectral range of a laser device comprising forming a series of effective refractive index perturbations along the optical path wherein the spacing between adjacent contributing interfaces is a uniform number of quarter material wavelengths.

### DESCRIPTION OF THE DRAWINGS

The invention is described in further detail below with reference to the accompanying drawings in which:

FIG. 1 illustrates a prior art slotted laser device comprising a single rectangular slot feature;

FIG. 2 is a plan view of the prior art structure shown in FIG. 1;

FIG. 3 is a schematic representation of the effects of the processing bias on the positioning of rectangular slots within a prior art device;

FIG. 4 shows a slotted laser device comprising a single angled slot;

FIG. 5 is a plan view of the device shown in FIG. 4;

FIG. 6 illustrates the critical dimensions in a laser according to the invention incorporating angled slot features and the effect on the refractive index caused by introducing angled slots;

FIG. 7 illustrates examples of different slot configurations, which may be used in the present invention;

FIG. 8 is the calculated mirror loss spectrum for a device incorporating angled slot features separated by 32 appropriate half material wavelengths to achieve single mode emission at 1.55 μm;

FIG. 9 illustrates the angled slot pattern used to obtain the calculated mirror loss spectrum shown in FIG. 8;

FIG. 10 illustrates in more detail the slot feature used in the simulations which produced the calculated mirror profiles in FIGS. 8, 11 and 12;

FIG. 11 is a calculated mirror loss spectrum obtained using a slot pattern in which the angled features are separated by different numbers of half material wavelengths, the slot pattern in question being designed to achieve single mode emission at 1.55 μm (note the very large effective free spectral range);

FIG. 12 consists of three overlaid calculated mirror loss spectra from 3 different slot patterns all designed to obtain single longitudinal mode emission at 1.55 μm (the solid, dashed and dotted spectra were respectively obtained using patterns in which the angled slot features were separated by 29, 44 and 62 half material wavelengths);

FIG. 13 illustrates an angled slot pattern used in calculation of the mirror loss spectra shown in FIG. 11;

FIG. 14(a-e) shows side profile views of a device at various at stages in the fabrication process.

FIG. 15 illustrates aspects of the tapered slot pattern, which was used to experimentally demonstrate the utility of the present invention in fabricating laser diode devices having large effective free spectral ranges;

FIG. 16 combines the spectra of a device operating at 10° C., 20° C., 30° C. and 85° C., which incorporated the slot pattern illustrated in FIG. 15;

FIG. 17 is the calculated mirror loss spectra for the slot pattern illustrated in FIG. 15;

FIG. 18 is the measured wavelength spectrum from a device designed to emit at 1.550 μm;

FIG. 19 is the measured wavelength spectrum from device designed to emit at 1.545 μm; and

FIG. 20 details the tapered slot/indentation pattern used in the devices giving rise to the spectra shown in FIGS. 17 and 18.

FIG. 21 illustrates an embodiment of the invention comprising chirped slots in which the lengths of individual slots differ.

### DETAILED DESCRIPTION OF THE INVENTION

Known slotted lasers suffer from the problems discussed above. These problems stem from the fact that prior art slot patterns form pairs of contributing interfaces (or interfaces providing feedback) separated by very small distances (typically <3 μm) as illustrated in FIG. 3. FIGS. 1 and 2 show a prior art device 1 formed of waveguiding layers 2 (typically having a multiple quantum well structure), upper cladding layer 4 and cap layer 5 with a facet 8 at either end. A ridge 3 extends longitudinally along the top of the device 1. One rectangular slot feature 6 is shown etched in the ridge 3 giving rise to slot faces 7 which are substantially perpendicular to the longitudinal direction of light propagation within the device. FIG. 3 illustrates how, as a result of offset due to process bias, the contributing interfaces 9 defined by faces 7 of rectangular slot 6 cannot be properly positioned with respect to other such contributing interfaces in the laser cavity with an accuracy high enough to ensure constructive interference at the appropriate wavelength. Specifically, in the case of such rectangular slots, each face of the slot will contribute to the overall optical feedback. The present invention reduces the optical feedback provided by the interfaces on a particular side of a given number of slots to such an extent that they can be ignored. This approach thus allows greater control of the lasers spectral content.

Where the length of a slot is constrained by the factors outlined above, any change in slot length will have profound effects on the mirror loss spectrum and thus emission wavelength of the device. As a result of the present invention this is no longer a problem since the spectral selectivity of the slot features is now no longer dependent upon the size of the slots themselves. The only dimensions which remain critical are the distances between those interfaces which provide a significant amount of optical feedback. Since these dimensions are typically more than an order of magnitude greater than the length of the slots themselves the accuracy with which these features have to be positioned is also relaxed by more than an order of magnitude.

FIGS. 4 and 5 show a device 10 according to the invention (having a similar structure to the device 1 in FIG. 1) with waveguiding layers 12, upper cladding layer 14, cap layer 15, ridge 13 and facets 17. In the embodiment shown an angled slot feature 16 is formed having a first face 18 perpendicular to the light propagation directions and a second face 19 angled with respect to the first face 18. The introduction of one or more slots (or equivalent features) causes perturbation of the lasing medium which is reflected in the change in refractive index profile (see FIG. 6). Interface 20 defined by an abrupt change in effective refractive index will contribute to optical feedback along the optical path, while interface 21 will not.

Considering FIGS. 3 and 6 and the problem of the bias associated with the etching process, it becomes apparent that with the present invention this is no longer an issue, since the length of the slot feature has now no bearing on the spectral distribution of the mirror loss spectrum of the device and thus no bearing on its emission wavelength. Moreover, if the interfaces which provide the bulk of optical feedback are all provided on same side of the slot features it is clear that process bias will effect all these interfaces in the same way, as shown in FIG. 6, thus having a reduced effect on the critical dimensions. Essentially, the present invention allows for lithographic tolerances to be relaxed when making single longitudinal mode devices at specified wavelengths. It also allows the emission wavelengths of adjacent laser elements in a bar format to be positioned precisely respect to each other. Moreover it allows this to done exactly with more relaxed lithographic tolerances than could be employed in the fabrication of known slotted lasers incorporating rectangular etched features.

The invention is based on the premise that structural features (such as slots, doped regions or the like) can be used to modify the effective refractive index profile of a device. (The effective refractive index is obtained by summing the products of the refractive index in a particular region of the laser cavity and the fraction of the optical intensity which is present in that region, and dividing this value by the integral over the spatial extent of the optical field.) Such structural features cause perturbation of the refractive index profile within the device, thus influencing performance characteristics. In other words, the faces of a slot etched in the ridge of a laser such as that shown in FIG. 4 cause interfaces between regions of higher and lower refractive index—the interfaces being defined by the physical characteristics of the slot. The present invention enables the performance characteristics of a laser to be enhanced by employing slot designs that perturb the refractive index profile so that there is only one contributing interface associated with each slot. In contrast rectangular slot features employed in prior art devices have two contributing interfaces associated with each slot.

Different types of etched features, which fulfill the requirement of providing only one contributing interface, are discussed below. Also discussed below are example patterns of such features that enable single longitudinal emission at a specified wavelength over an extended temperature range. It is noted that the patterns and their constituent etched features can be used interchangeably to achieve the desired spectral content.

As previously mentioned each slot pattern has two distinct design elements associated with it, the first is shape of etched slot features the second is positions of these features with respect to one another and the facets of the laser cavity. In general any slot configuration in which optical feedback from one of the slot interfaces is suppressed may be employed in the present invention. For the purpose of the invention therefore a slot should produce a refractive index profile such as that shown in FIG. 6 having a first contributing interface 20 and a second non-contributing interface 21. In the case of the non-contributing interface 21, the desired refractive index effect may be produced by the introduction of an angled, sloped, stepped, curved (or combination thereof) or other suitable slot into the ridge 13. FIG. 6 depicts slots 22 each having a conventional planar face 18 and a ‘v-shaped’ face 22. Any other effect upon refractive index which has the result that the second interface does not contribute substantially to optical feedback within the along the longitudinal optical path will suffice for the purposes of the invention. The key aspect of the present invention is therefore that the refractive index profile associated with at least one perturbation or slot is such that only one of the two longitudinal interfaces contributes to optical feedback.

FIG. 7 illustrates examples of different slot configurations, which may be used in the present invention, specifically the slot features (a) and (e) are referred to as being tapered, the features (c) and (g) are referred to as being curved, the features (d) and (f) are referred to as being corrugated, feature (b) is referred to as being angled and the feature (h) is referred to as being stepped tapered. The common trait being that they each have one interface which is substantially perpendicular to the direction of light propagation in the laser cavity (contributing to optical feedback), while the other side of the slot is designed to suppress optical feedback (e.g. by being curved or angled with respect to the first interface). The selection of devices shown in FIG. 7 is not an attempt to provide a comprehensive set of designs instead it merely illustrates a number of possible implementations.

Preferably each slot defines a first interface (or contributing interface) which is substantially planar and substantially perpendicular to the longitudinally extending optical path and a second interface (or feedback suppressing interface) which is substantially curved or angled with respect to the first interface. The contributing interface acts in the usual manner to provide optical feedback to L/N^{th} modes while the suppressing interface is designed to avoid adding to the optical feedback within the laser cavity. Having the second interface curved or angled with respect to the first reduces the amount of optical feedback it can provide to any particular longitudinal mode for two reasons. Firstly, light which interacts with a curved or angled interface is more likely (than light interacting with a planar interface aligned perpendicular to its direction of propagation) to be scattered out of the laser cavity. Secondly, light which is reflected back into lasing mode from different parts of such an interface will not be in phase, thus the optical feedback it provides will be distributed over a wavelength range which encompasses a number of longitudinal modes of the laser cavity thus diluting its impact in determining spectral content.

Specifying the emission wavelength of a laser diode, by etching features discussed above can be achieved by placing the interfaces which provide the bulk of the optical feedback, i.e. the straight interfaces which are perpendicular to the direction of light propagation, at distances from one another that correspond to multiples of half the free space emission wavelength divided by effective refractive index of the lasing mode. At this juncture it is worth defining λₘ which is the wavelength of light in the laser cavity, this is also known as the material wavelength. The material wavelength is related to the free space wavelength, λ, by the following equation

$${λ}_{m} = \frac{λ}{{n}_{eff}} \qquad ( 2 )$$

The problem of achieving single longitudinal mode laser emission at a specified wavelength over a particular temperature range is also addressed by the present invention. In order to do this it is necessary to discriminate against enough of the longitudinal modes of cavity to cope with changes in the laser's gain spectrum that occur over the temperature interval in question. Once the number of longitudinal modes (of the unperturbed structure) which must be discriminated against for a particular application is determined the appropriate slot pattern can be determined. For the most basic type of slot patterns, i.e. those in which all contributing interfaces providing the bulk of the optical feedback are separated by the same distance, the effective free spectral range, Δλ_{eff}, can be calculated from the formula

$${Δλ}_{eff} = \frac{d}{L} Δλ \qquad ( 3 )$$

(where d is the distance between the contributing interfaces of the slot features, L is the cavity length, and Δλ is the free spectral range of the Fabry Perot cavity).

The two aspects of spectral selectivity discussed thus far i.e. the ability to specify the wavelength and the extent of the effective free spectral range, are clearly evident in FIG. 8 which shows the calculated mirror loss spectrum of one embodiment of the invention, a device which has ten etched tapered slot features. These features are positioned along the cavity so as to produce lasing emission at 1.55 μm, as such their high feedback interfaces were separated by a distance of sixteen material wavelengths. Since lasing emission occurs at wavelengths which correspond to minima in the mirror loss spectrum it is immediately apparent that the effective free spectral range of this laser is 45 nm, assuming the gain spectrum is sufficiently flat, this is the same value as that obtained using Equation 3. It is also apparent that a laser diode whose gain spectrum is centred close to 1.55 μm, and which incorporates this pattern, will lase in a single longitudinal mode at 1.55 μm. Given that the gain spectrum of the active region in such devices tunes with temperature at a rate of approximately 0.6 nm/° C. such a device incorporating the pattern of slot features discussed would provide single longitudinal mode emission over a temperature range of T₁±T₂ (where T₁ is the temperature at which the gain spectrum is centred around the wavelength of interest, and T₂ is by

$${T}_{2} = \frac{{Δλ}_{eff} / 2}{\frac{d G}{d T}} \qquad ( 4 )$$

where dG/dT is the rate at which the gain peak tunes with temperature). In this case it is possible to achieve single longitudinal mode emission over a temperature interval of about 80° C.

FIG. 9 illustrates the positions these slot features in the laser cavity. The slot features themselves have an average length of 0.3 μm, their associated contributing interfaces having an effective refractive index step of 0.008, while the angled face of each slot feature consisted of eight sub-units each providing an effective index step of 0.001, and staggered along the cavity by about 10 nm (see FIG. 10). The portion of the laser cavity containing the tapered slots is characterised by a series of slots etched at constant spacing of 32 half material wavelengths.

FIG. 11 is the calculated mirror loss spectrum for a device according to a second embodiment comprising a different pattern of ten tapered slot features (see FIG. 13). This embodiment exhibits a greater effective free spectral range and therefore will maintain single longitudinal emission over far greater temperature ranges. Specifically the effective free spectral range is greater than 80 nm, this would provide signal longitudinal mode emission over a temperature range about 160° C. Before considering the details of the pattern of etch features, which has the mirror spectrum shown in FIG. 11 it is worth considering the following: FIG. 12 shows the mirror loss spectra for three simple slot patterns analogous to that shown in FIG. 9, all designed to obtain single longitudinal mode at the same wavelength, in this specific case the wavelength in question in 1.55 μm. With respect to the patterns of tapered slot features which have the mirror loss spectra shown in FIG. 12 it is important to note that they differ only by virtue of the fact that their perpendicular planar faces are separated by different numbers of half material wavelengths. It can be seen that the only wavelength at which these patterns constructively interfere is the wavelength at which they are designed to lase at, i.e. 1.55 μm. Thus the effective free spectral range is enhanced by combining patterns of slot features (that have different number of half material wavelengths between the slot faces defining the feedback contributing interfaces). Such an approach smears out the parts of the mirror loss spectrum on each side of the wavelength of interest that are highly oscillatory, creating a more uniform mirror loss spectrum except at the wavelength of interest.

The slot pattern (FIG. 13) which was used to obtain the mirror loss spectra in FIG. 11 can be thought of as a combination of the three patterns which were used to produce the various mirror loss spectra found in FIG. 12 i.e. three individual series having slot separations of 29, 44 and 62 half material wavelengths. As the only wavelength at which this combination of patterns constructively interferes is the design wavelength, the result is an enhanced effective free spectral range. This approach offers an improvement over simpler slot patterns, which consist of just one fixed number of half material wavelengths between adjacent slot faces defining the contributing interfaces.

A number of laser diode devices incorporating various configurations of tapered slot features were fabricated. These devices were fabricated using standard processing techniques. The steps used in the manufacture of the devices, whose characteristics are detailed here, were as follows.
(1) Growth of a standard AlInGaAs/InP epitaxial laser diode structure on an InP substrate;
(2) Formation of a resist pattern for ridge/slot features using standard lithographic techniques;
(3) Etching the ridge and slot features;
(4) Application of a dielectric coating;
(5) Etching an opening in the dielectric along the top of the ridge structures;
(6) Deposition of contact metal;
(7) Cleaving into bar format;
(8) Application of facet coating (optional); and
(9) Singulation into individual devices.

Steps 2, 3, 4, 5 and 6 respectively are illustrated in FIG. 14, (a) to (e).

The slot patterns which were incorporated into the fabricated devices were designed to demonstrate two principal aspects of the invention. Namely the ability to fabricate single longitudinal mode laser diodes which emit at a stipulated wavelength, and the ability to manipulate the mirror loss spectrum of a laser diode so as to allow a laser emitting in a single longitudinal to operate over a predetermined temperature range without suffering from mode hops. It is noted that the data below was obtained on prototype samples, which were fabricated at the same time, and that the samples used in this these experiments had a high reflectivity coating applied to one facet, and a low reflectivity coating applied to the other facet.

First the task of achieving single longitudinal mode operation over a predetermined temperature range is considered. The device was designed to lase in a single longitudinal at λ=1.585 μm, given an operating temperature 20° C. The measured lasing wavelength turned out to be 1.577 μm (operating at a temperature 20° C.). The difference between the design wavelength and experimentally measured wavelength was attributed to the fact that the effective index of the guided mode was not known to a high enough accuracy at design time. The design of the tapered slot features, which were incorporated into the first set of devices, is shown in FIG. 15. Given that there are twenty material wavelengths between the contributing interfaces of the slot features, the effective free spectral range of the device was calculated to be 36 nm. In total the device contained ten such etched features, the feature closest to the low reflectivity coating was positioned such that its contributing interface was 50 μm from the crystal facet that that is adjacent to the low reflectivity coating. FIG. 16 shows the wavelength spectra obtained from the device at 10° C., 20° C., 30° C. and 85° C. To allow interpretation of the graph it is noted the emission wavelength always increases with temperature. Mode hop free operation is demonstrated range over the temperature range 20° C. to 85° C., by virtue of the fact that the rate at which the wavelength tuned with temperature, over this range, was measured to be 0.1 nm/° C. It is also noteworthy that the emission wavelength at 10° C. is separated by approximately 36 nm from the emission wavelength 20° C. This shows that the effective free spectral range agrees with that predicted by theory (FIG. 17). The large effective free spectral ranges achieved with the present invention have not been obtained using devices incorporating conventional slot patterns.

Next, the ability to specify the emission wavelength of individual laser diode devices is considered. Two devices were designed to lase in a single longitudinal mode, the first at λ=1.550 μm and the second at λ=1.545 μm. In practice the emission of the first device was at 1.544 μm (FIG. 18), while that of the second was at 1.439 μm (FIG. 19). The design of the tapered indentations incorporated into this device is shown in FIG. 20 (this pattern demonstrates the utility of the present invention in fabricating laser diode devices whose emission wavelength can be specified with a high degree of accuracy). In total each device contained ten pairs of such indentations, the indentations closest to the low reflectivity coating were positioned such that their contributing interfaces were 50 μm from the crystal facet that that is adjacent to the low reflectivity coating. The only difference between patterns of indentations was that in first case the contributing interfaces of the slot features were designed to be spaced at twenty material wavelength appropriate to achieving emission a 1.550 μm, while in the second pattern the contributing interfaces of the slot features were designed to be separated by twenty wavelengths appropriate to achieving emission at 1.545 μm. As before the inability to specify the wavelength correctly is due to the fact that the precise value of the effective index was not known at design time. However it is noted that although the wavelengths of the individual devices are both 6 nm away from their respective design wavelength's, the separation between these wavelength's is 5 nm as specified. It is also noted that since the effective index of the lasing mode may be calculated from the wavelength emission spectra, the emission wavelengths of future devices may be specified much more accurately.

Turning to FIG. 21, a further embodiment a laser according to the invention comprises a rectangular slot pattern which allows some of the manufacturing tolerances usually associated with these perturbation features to be relaxed. According to this embodiment the lengths of individual slots are varied (i.e. the lengths of two or more slots are different from each other). The first face (or contributing face) of each slot is aligned (or in phase) so as to interfere constructively with light reflected from other such faces and thus contribute to optical feedback along the optical path. However, the corresponding second faces are out of phase and cause destructive interference and thus are non-contributing in terms of the optical feedback along the optical path.

As with other embodiments, this embodiment of the invention has the advantage of facilitating greater manufacturing tolerances. From a manufacturing perspective the critical tolerances are reduced from the placement of two faces per slot (as is the case in prior art devices, as shown for example in FIGS. 1 to 3) to one face per slot as indicated in FIG. 21.

1. A method of manufacturing a laser device comprising the steps of:
a) defining a desired spectral characteristic,
b) defining a desired far field emission pattern,
c) selecting a suitable ridge laser design for the desired spectral characteristic,
d) determining the positions of index perturbations for the ridge laser to achieve a desired spectral characteristic, and
e) determining the shape, length and/or depth of the index perturbations to achieve the desired far field emission pattern.

2. A method according to claim 1, wherein the desired spectral characteristic is a fundamental frequency.

3. A method according to claim 1, wherein the desired far field emission pattern is a FWHM for each of the perpendicular and parallel far fields of less than 27 degrees.

4. A method according claim 1, wherein the desired far field emission pattern is a difference in the FWHM for the perpendicular and parallel far fields of less than 5 degrees.

5. A method according to claim 4, wherein the difference is less than 2 degrees.

6. A method according to claim 4, wherein the difference is less than 1 degree.

7. A method of manufacturing a semiconductor device for emitting light in a first direction comprising the step of creating at least one index perturbation in the semiconductor device aligned in a direction substantially transverse to the first direction to achieve a desired spatial distribution of the emission.

8. A method according to claim 7, wherein the at least one index perturbation may comprise a pattern of index perturbations. Suitably, the semiconductor device comprises a laser, for example a ridge waveguide laser.

9. A method according to claim 7, wherein the semiconductor device is a slotted laser.

10. A method according to claim 9, wherein the perturbation is a slot.

11. A method according to claim 10, wherein one or more of the following: slot depth, slot length and slot shape is selected to contribute to the desired emission pattern.

12. A method according to claim 7, wherein the index perturbation is provided by one or the following or a combination thereof: introduction of a dopant, etching and ion implantation.

13. A semiconductor light emitting device comprising a longitudinal active region for producing the light and one or more effective refractive index perturbations disposed along the longitudinal axis and aligned transverse thereto, wherein at least one of the refractive index perturbations is dimensioned to effect a desired emission pattern from the active region.

14. A semiconductor device according to claim 11, wherein the device is a laser.

15. A semiconductor device according to claim 12, wherein the laser is a ridge waveguide laser.

16. A semiconductor device according to claim 13, wherein the at least one perturbation is formed by a slot defined in the ridge.

17. A semiconductor device according to claim 14 wherein the length, depth and or shape of the slot was selected to contribute to a desired far-field emission pattern.

18. A semiconductor device according to claim 12, wherein the at least one effective refractive index perturbation is formed by one or more indentations defined in the side of the ridge of the laser or more generally by indentations defined in the ridge.

19. A method of manufacturing a laser comprising the steps of: (1) forming a laser cavity with a lasing medium, the laser cavity defining a longitudinally extending optical path and having a facet at either end, and (2) forming a plurality of perturbations into the laser cavity, wherein the shape and/or dimensions of the plurality of perturbations are selected to provide a desired far-field emission pattern for the laser wherein the cavity is formed with a longitudinally extending ridge with at least one perturbation provided by etching a slot in the ridge and wherein at least one of the following:
a) slot depth,
b) slot width, and
c) slot shape,
selected to contribute to the desired emission pattern.

20. A method of tuning a ridge laser, the method including the steps of providing a first pattern of perturbations to define the spectral emission characteristics of the laser and a second pattern of perturbations to define the spatial emission characteristics of the laser.

21. A slotted ridge wave-guide laser having a substantially non-astigamtic emission pattern.

22. A slotted ridge wave-guide laser according to claim 19 wherein non-astigmatic is defined as a ratio between the perpendicular and parallel far field FWHMs of less than 1.1.
